(19) United States
(12) Patent Application Publication
(10) Pub. No.: US 2022/0190142 A1
(43) Pub. Date: Jun. 16, 2022

(54) METHOD OF MANUFACTURING TRANSISTOR

(71) Applicant: Samsung Display Co., Ltd., Yongin-Si (KR)

(72) Inventors: JAEWOO JEONG, Suwon-si (KR); Jong Oh SEO, Seoul (KR)

(21) Appl. No.: 17/550,230

(22) Filed: Dec. 14, 2021

(30) Foreign Application Priority Data
Dec. 14, 2020 (KR) 10-2020-0174159

(51) Int. Cl. H01L 29/66; H01L 29/786; H01L 21/265; H01L 21/266

(52) U.S. Cl. CPC H01L 29/66757; H01L 29/78675; H01L 21/266; H01L 21/26513; H01L 29/78696

(57) ABSTRACT

A method of manufacturing transistor may include forming an active layer on a base substrate, forming a sacrificial layer on the active layer, doping a first dopant ion in the active layer through a first ion implantation process, removing the sacrificial layer, forming a gate insulating layer; and forming a gate electrode on the gate insulating layer.

### CROSS-REFERENCE TO RELATED APPLICATION

This application claims priority to and the benefit of Korean Patent Application No. 10-2020-0174159, filed on Dec. 14, 2020, which is incorporated by reference for all purposes as if fully set forth herein.

### BACKGROUND

### Field

Embodiments described herein relate to a method of manufacturing transistor.

### DISCUSSION OF THE BACKGROUND

A display device may include a pixel and a driving part for driving the pixel. The pixel may include at least one of transistors.

As a resolution of the display device increases, a size of the pixel may decrease, and a size of the transistor included in the pixel may decrease. When the transistor with a relatively small size is driven at high speed, an unintended afterimage may occur on the display device. Accordingly, a display performance of the display device may be deteriorated.

### SUMMARY

Embodiments provide a method of manufacturing transistor.

A method of manufacturing transistor may include forming an active layer on a base substrate, forming a sacrificial layer on the active layer, doping a first dopant ion in the active layer through a first ion implantation process, removing the sacrificial layer, forming a gate insulating layer; and forming a gate electrode on the gate insulating layer.

In an embodiment, the sacrificial layer may include a silicon oxide.

In an embodiment, the sacrificial layer may be formed through a chemical vapor deposition method.

In an embodiment, the sacrificial layer may be removed through a wet etching method.

In an embodiment, the sacrificial layer may be removed through a chemical mechanical polishing (CMP) method.

In an embodiment, the first dopant ion may include a group III element.

In an embodiment, the group III element may include boron (B).

In an embodiment, the first dopant ion may include a group V element.

In an embodiment, the group V element may include phosphorus (P).

In an embodiment, a doping amount of the first dopant ion in the active layer may have a peak in a region less than or equal to 20 nm from a surface of the active layer.

In an embodiment, the doping amount of the first dopant ion in the active layer may be about 10¹² ions/cm² or more.

In an embodiment, the method may further include sequentially forming an insulating layer and a gate electrode forming layer on the active layer after removing the sacrificial layer, patterning the gate electrode forming layer to form a gate electrode on the insulating layer, forming an interlayer insulating layer on the gate electrode, and forming a source electrode and a drain electrode on the interlayer insulating layer.

In an embodiment, the method may further include doping a second dopant ion on the active layer through a second ion implantation process after patterning the gate electrode using the patterned gate electrode as a mask.

In an embodiment, an upper surface of the doped part may contact the insulating layer.

A method of manufacturing transistor may further include forming an active layer on a base substrate, forming a sacrificial layer on the active layer, doping a first dopant ion in the active layer through a first ion implantation process, removing the sacrificial layer, forming a gate insulating layer, and forming a gate electrode on the gate insulating layer.

In an embodiment, the first dopant ion may include a group III element and the second dopant ion may include a group V element.

In an embodiment, the group III element may include boron and the group V element may include phosphorous.

In an embodiment, a doping amount of the first dopant ion in the active layer may have a peak in a region less than or equal to 20 nm from a surface of the active layer and a doping amount of the first dopant ion in the active layer may be about 10¹² ions/cm² or more.

In an embodiment, a doping amount of the second dopant ion in the active layer may have a peak in a region less than or equal to 20 nm from a surface of the active layer and a doping amount of the second dopant ion in the second surface may be about 10¹² ions/cm² or more.

### BRIEF DESCRIPTION OF THE DRAWINGS

The accompanying drawings, which are included to provide a further understanding of the inventive concept and are incorporated in and constitute a part of this specification, illustrate exemplary illustrative embodiments of the inventive concept, and together with the description serve to explain the inventive concepts.

FIG. 1 is a cross-sectional view illustrating a transistor according to an embodiment of the present inventive concept.

FIG. 2 is a plan view explaining an afterimage of a display device including a conventional transistor.

FIG. 3 is a graph explaining a channel layer of the transistor of FIG. 1.

FIG. 4 is a diagram explaining a method of manufacturing a transistor according to an embodiment of the present inventive concept.

FIG. 5 is a graph for explaining an ion implantation process of FIG. 4.

FIG. 6 is a cross-sectional view enlarging an area A of FIG. 4.

FIG. 7 is a diagram illustrating a method of manufacturing a transistor according to another embodiment of the present inventive concept.

FIG. 8 is a cross-sectional view enlarging an area A of FIG. 7.

### DETAILED DESCRIPTION

Hereinafter, embodiments of the present inventive concept will be explained in detail with reference to the accompanying drawings.

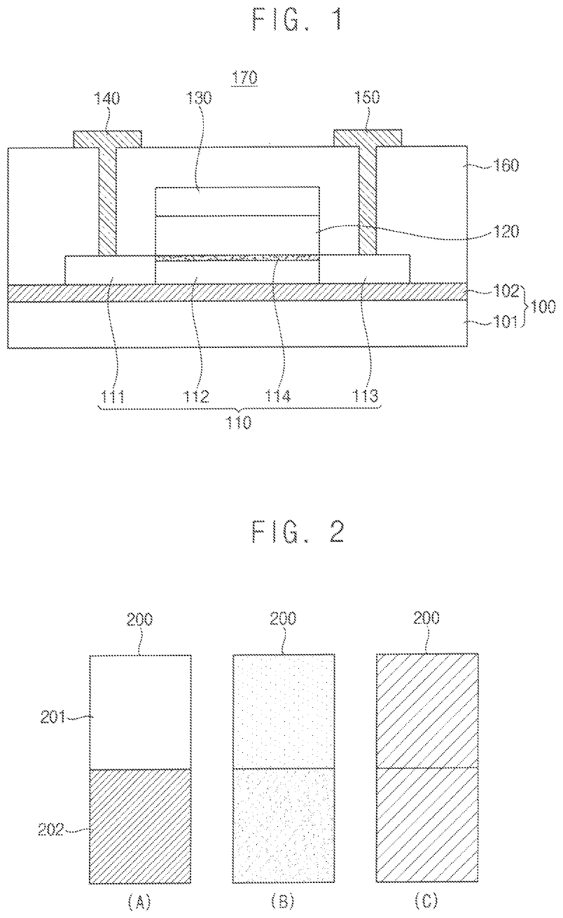

FIG. 1 is a cross-sectional view illustrating a transistor according to an embodiment of the present inventive concept.

Referring to FIG. 1, a transistor 170 may include an active pattern 110, an insulating pattern 120, a gate electrode 130, a source electrode 140, a drain electrode 150, and an interlayer insulating layer 160 disposed on a base substrate 100.

The base substrate 100 may include a substrate 101 and a buffer layer 102. The substrate 101 may include a glass. The buffer layer 102 may be disposed on the substrate 101. For example, the buffer layer 102 may prevent a contaminant on the substrate 101 from diffusing into the active pattern 110. The buffer layer 102 may include inorganic insulating material.

The active pattern 110 may be disposed on the base substrate 100. The active pattern 110 may include polycrystalline silicon. The active pattern 110 may include a source part 111, a channel part 112, and a drain part 113. When a voltage higher than a threshold voltage is applied to the gate electrode 130, a charge carrier may move from the source part 111 to drain part 113 through the channel part 112.

The channel part 112 may include a doped part 114. The doped part 114 may include a dopant for changing properties of the channel part 112. As the doped part 114 is present in the channel part 112, an amount of the charge carrier may be increased. The doped part 114 may be formed through ion implantation of a dopant into the channel part 112.

The insulating pattern 120 may be disposed on the active pattern 110. The insulating pattern 120 may electrically insulate the active pattern 110 and the gate electrode 130.

The gate electrode 130 may be disposed on the active pattern 120. The gate electrode 130 may generate an electric field. Accordingly, the gate electrode 130 may control an amount of the charge carrier flowing through the channel part 112.

The source electrode 140 may be connected to the source part 111. The drain electrode 150 may be connected to the drain part 113. The charge carrier may flow between the source electrode 140 and the drain electrode 150.

The interlayer insulating layer 160 may cover the active pattern 110, the insulating pattern 120, and the gate electrode 130. The interlayer insulating layer 160 may electrically insulate the active pattern 110, the gate electrode 130, the source electrode 140, and the drain electrode 150.

FIG. 2 is a plan view explaining an afterimage of a display device including a conventional transistor.

Referring to FIG. 2, a display device 200 may include an upper area 201 and a lower area 202. The upper area 201 and the lower area 202 may display different image.

Referring to (A) of FIG. 2, a white pattern may be displayed in the upper area 201 and a black pattern may be displayed in the lower area 202 for about 10 seconds. Thereafter, an electric signal for displaying a 48 gray pattern in the upper area 201 and the lower area 202 may be transmitted to the display device 200.

Referring to (B) of FIG. 2, after receiving the electric signal, the 48 gray pattern may not be displayed immediately in the upper area 201 and the lower area 202. In this case, a difference in luminance may occur between a pattern displayed in the upper area 201 and a pattern displayed in the lower area 202.

Referring to (C) of FIG. 2, after a certain period of times has elapsed from the electric signal is received, the difference in luminance may be about 0.4% or less. The certain period of times required for the difference in luminance to become about 0.4% or less is defined as an afterimage time TA.

The afterimage time TA may be increased by doping the dopant to the buffer layer 102 when doping the dopant in the channel part 112. The afterimage time TA may be reduced by forming the doped part 114. The afterimage time TA may be affected by hysteresis.

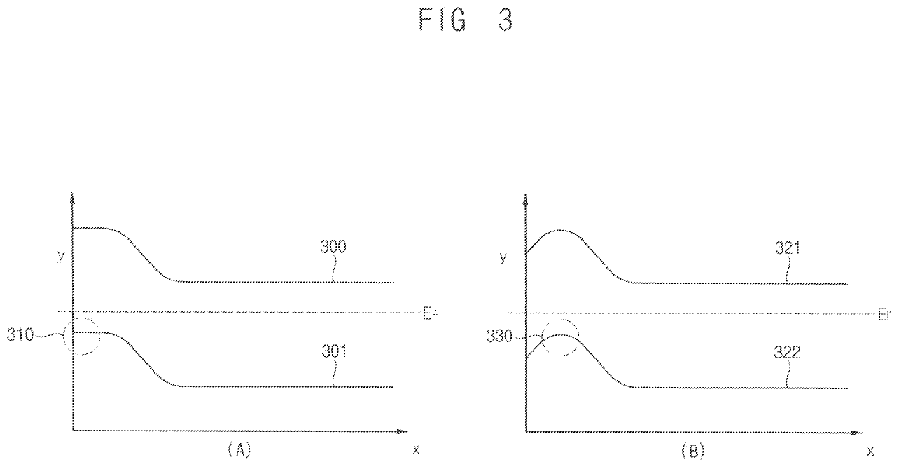

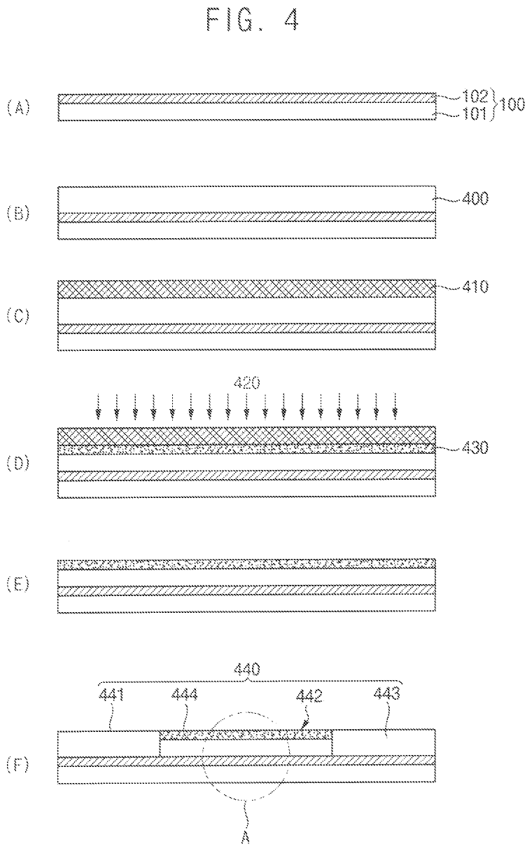

FIG. 3 is a graph explaining a channel layer of the transistor of FIG. 1.

Referring to FIG. 3, an x-axis corresponds to a direction from an upper surface of the active pattern 110 to a lower surface of the active pattern 110, and a y-axis indicates a magnitude of electron energy. Fermi level EF is shown by a dotted line.

Referring to (A) of FIG. 3, when the doped part 114 is not present in an upper area of channel part 112, a conduction band 300 and a valence band 301 may form a surface channel 310. The surface channel 310 may be formed just below an upper surface of the channel part 112. In this case, the charge carrier may flow through the surface channel 310. Since the surface channel 310 is formed just below the upper surface of the channel part 112, the surface channel 310 may be affected by the insulating pattern 120 dispose on the channel part 112. Accordingly, the charge carrier may be affected by the insulating pattern 120 and the afterimage time TA may be increased.

Referring to (B) of FIG. 3, when the doped part 114 is present in the upper area of the channel part 12, a conduction band 321 and a valence band 322 may form a buried channel 330. The buried channel 330 may be formed inside the channel unit 112. In this case, the charge carrier may flow through the buried channel 330. Since the buried channel 330 may be formed a predetermined distance below the surface of the channel part 112, the buried channel 330 may not be affected by the insulating pattern 120. Accordingly, hysteresis may be decreased, and the afterimage time TA may be reduced.

FIG. 4 is a diagram explaining a method of manufacturing a transistor according to an embodiment of the present inventive concept.

Referring to (A) of FIG. 4, a base substrate 100 may be formed. The base substrate 100 may include a substrate 101, and a buffer layer 102 disposed on the substrate 101.

Referring to (B) of FIG. 4, an active layer 400 may be formed on the buffer layer 102. The active layer 400 may include amorphous silicon. The amorphous silicon may be converted into polycrystalline silicon by an excimer laser annealing (ELA) process.

Referring to (C) of FIG. 4, a sacrificial layer 410 may be formed on the active layer 400. The sacrificial layer 410 may include silicon oxide or silicon nitride. A method of forming the sacrificial layer 410 is not particularly limited and the sacrificial layer 410 may be formed using known methods. For example, the sacrificial layer 410 may be formed through chemical vapor deposition (CVD) method.

Referring to (D) of FIG. 4, in a first ion implantation process, a first dopant ion 420 may be doped into the active layer 400 through the sacrificial layer 410. Accordingly, a pre-doped part 430 doped with the first dopant ion 420 may be formed on the active layer 400. In the first ion implantation process, the active layer 400 may be irradiated with the first dopant ions 420 which are accelerated by an acceleration voltage and pass through the sacrificial layer 410. By adjusting a magnitude of the acceleration voltage and a thickness of the sacrificial layer 410, an average penetration depth of the first dopant ion 420 injected into the active layer 400 may be adjusted. The first dopant ion 420 may include group III element or group V element according to a type of a transistor. For example, the group III element may include boron (B). The boron may be relatively light, and accordingly, a doping concentration may be easy to adjust. For example, the group V element may include phosphorus (P).

Referring to (E) of FIG. 4, the sacrificial layer 410 may be removed. A method of removing the sacrificial layer 410 is not particularly limited, and the sacrificial layer 410 may be removed using known methods. For example, the sacrificial layer 410 may be removed through wet etching method. For example, the sacrificial layer 410 may be removed through a chemical mechanical polishing (CMP) method. When the chemical mechanical polishing (CMP) method is used, an upper surface of the active layer 400 may have relatively flat surface. As the sacrificial layer 410 is removed, the first dopant ion 420 implanted into the sacrificial layer 410 through the first ion implantation process may also be removed.

Referring to (F) of FIG. 4, the active layer 400 including the pre-doped part 430 may form a channel part 442. A method of forming of the active layer 400 is not particularly limited, and known methods may be used. For example, the method of forming of the active layer 400 may include forming an insulating layer on the active layer 400, forming a gate electrode on the insulating layer, and doping a second dopant ion on the active layer 400 through a second ion implantation process.

During the forming of the active layer 400, the active layer 400 located under the gate electrode may become the channel part 442. The gate electrode may serve as a self-aligned mask when implanting the second dopant ion, and may prevent the second dopant ion from being doped into the channel part 442. Accordingly, the pre-doped part 430 existing in an upper area of the active layer 400 may become the doped part 444 in an upper area of the channel part 442. The doped part 444 may form the buried channel 330 in the channel part 442. Accordingly, the afterimage time TA may be reduced.

During the second ion implantation process, the active layer 400 covered by the gate electrode may be a source part 441 and a drain part 443. In this case, the pre-doped part 430 may exist in some of an upper area of the source part 441 and an upper area of the drain part 443. Generally, an amount of the second dopant ion implanted through the second ion implantation process may be greater than an amount of the first dopant ion 420 doped in the pre-doped part 430. Accordingly, the pre-doped part 430 present in some of the upper area of the source part 441 and the upper area of the drain part 443 may be ignored.

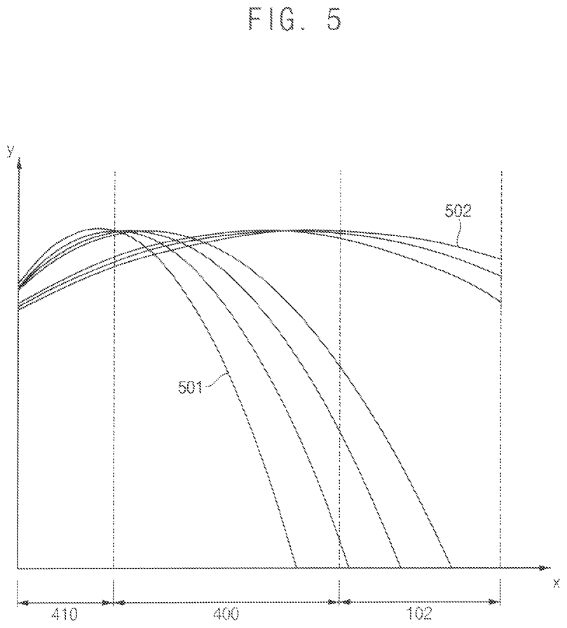

FIG. 5 is a graph for explaining an ion implantation process of FIG. 4.

Referring to FIG. 5, an x-axis corresponds to a distance from an upper surface of the sacrificial layer 410 to a lower surface of the buffer layer 102, and a y-axis indicates a concentration of the first dopant ion 420 implanted through the first ion implantation process. In the first ion implantation process, an acceleration voltage may be about 5 KeV to about 100 KeV. A thickness of the sacrificial layer 410 may be about 20 nm, and a thickness of the active layer 400 may be about 50 nm.

In one embodiment, in the first ion implantation process, the acceleration voltage of the first dopant ion 420 may be about 8.5 KeV. In this case, the concentration gradient of the first dopant ion 420 is shown by a first line 501. A concentration of the first dopant ion 420 may be about 10¹⁷ ions/cm³ in an upper surface of the active layer 400. The first dopant ion 420 may not be present in a lower surface of the active layer 400 when conditions for the first ion implantation process is controlled appropriately. Accordingly, the buried channel 330 may be formed in the channel part 442.

In one embodiment, in the first ion implantation process, the acceleration voltage of the first dopant ion 420 may be about 50 KeV. In this case, the concentration gradient of the first dopant ion 420 is shown by a second line 502. The first dopant ion 420 may have a maximum concentration near the lower surface of the active layer 400. The first dopant ion 420 may exist in the buffer layer 102 other than the active layer 400. Accordingly, hysteresis may be increased and the afterimage time TA may be increased.

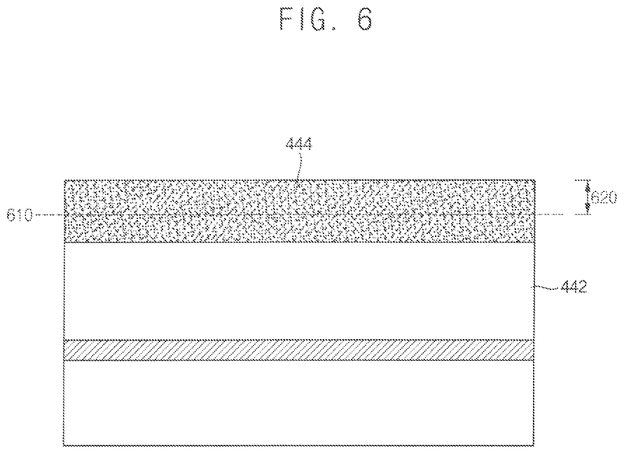

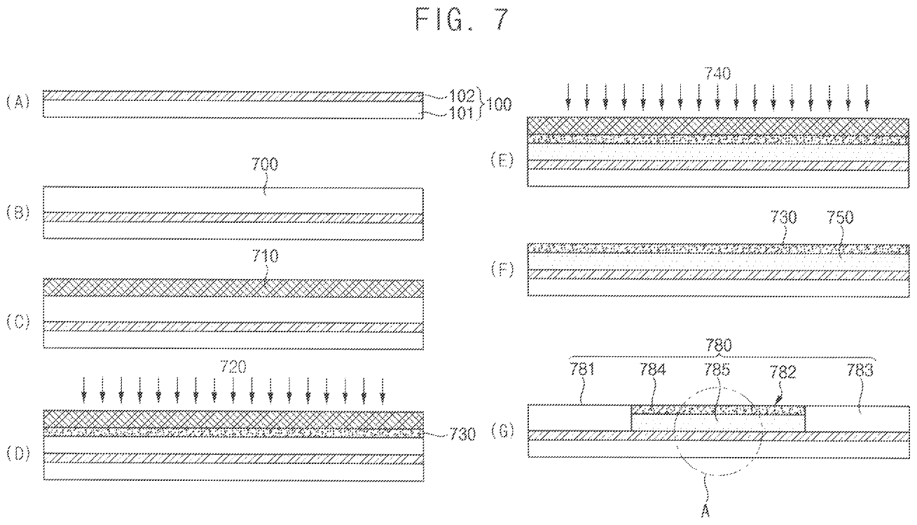

FIG. 6 is a cross-sectional view enlarging an area A of FIG. 4.

Referring to FIG. 6, the doped part 444 may include an average penetration depth 610 having the highest concentration of the first dopant ion 420 implanted through the first ion implantation process. In the first ion implantation process, the first dopant ion 420 may be accelerated by the acceleration voltage. The upper surface of the sacrificial layer 410 may be irradiated with the first dopant ion 420. The first dopant ion 420 may collide with an atomic structure constituting the sacrificial layer 410 or may be implanted into the sacrificial layer 410 without colliding with the atomic structure constituting the sacrificial layer 410. Accordingly, the first dopant ion 420 doped in the sacrificial layer 410 and the doped part 444 may have a vertical concentration gradient. The vertical concentration gradient may have a Gaussian distribution. Accordingly, the doped part 444 may include the average penetration depth 610 having the highest concentration of the first dopant ion 420.

In this case, the average penetration depth 610 in the doped part 444 may be adjusted by adjusting a magnitude of the acceleration voltage. For example, a first depth 620 from an upper surface of the doped part 444 to the average penetration depth 610 may be adjusted to be about 20 nm or less.

In addition, the concentration of the first dopant ion 420 may be adjusted by adjusting an implanting time of the first ion implantation process. For example, a doping amount of the first dopant ion 420 in the first surface 610 may be about 10¹² pieces/cm² or more.

FIG. 7 is a diagram illustrating a method of manufacturing a transistor according to another embodiment of the present inventive concept.

Referring to (A) of FIG. 7, a base substrate 110 may be formed. The base substrate 110 may include a substrate 101, and a buffer layer 102 disposed on the substrate 101.

Referring to (B) of FIG. 7, an active layer 700 may be formed on the buffer layer 102. The active layer 700 may include an amorphous silicon. The amorphous silicon may be converted into polycrystalline silicon by an excimer laser annealing (ELA) process.

Referring to (C) of FIG. 7, a sacrificial layer 710 may be formed on the active layer 700. The sacrificial layer 710 may include silicon oxide or silicon nitride.

Referring to (D) of FIG. 7, in a first ion implantation process, a first dopant ion 720 may be doped on the sacrificial layer 710. Accordingly, a first pre-doped part 730 doped with the first dopant ion 720 may be formed on the active layer 700. In the first ion implantation process, the sacrificial layer 710 may be irradiated with the first dopant ions 720 which are accelerated by an acceleration voltage and pass through the sacrificial layer 410. By adjusting a magnitude of the acceleration voltage and a thickness of the sacrificial layer 710, an average penetration depth of the first dopant ion 720 injected into the active layer 400 may be adjusted.

Referring to (E) of FIG. 7, in a second ion implantation process, the sacrificial layer 710 may be irradiated with the second dopant ion 740. In the second ion implantation process, the sacrificial layer 710 may be irradiated with the second dopant ions 740 which are accelerated by an acceleration voltage. By adjusting a magnitude of the acceleration voltage and a thickness of the sacrificial layer 710, an average penetration depth of the second dopant ion 740 injected into the active layer 400 may be adjusted.

A second pre-doped part 750 doped with the second dopant ion 740 may be formed in the active layer 700 through the second ion implantation process. In an embodiment, as shown in FIG. 7, the second pre-doped part 750 may be formed throughout the active layer 700. In FIG. 7, a portion where the second pre-doped part 750 overlaps with the first pre-doped part 730 is omitted. The second pre-doped part 750 may increase an amount of the charge carrier, and so, may decrease the afterimage time TA.

The second pre-doped part 750 may be doped with a dopant having opposite type to the first dopant ion 720. So, a threshold voltage of a transistor may be adjusted. For example, the first dopant ion may include a group III element and the second dopant ion may include a group V element. Electrons may be insufficient in the active layer 700 due to the first pre-doped portion 730 doped with the group III element. In this case, by generating the second pre-doped part 750 doped with the group V element, electrons may be supplied to the active layer 700.

The group III element may include boron (B) and the group V element may include phosphorus (P). The boron may be relatively light, and accordingly, the doping concentration may be easy to adjust.

Referring to (F) of FIG. 7, the sacrificial layer 710 may be removed. A method of removing the sacrificial layer 710 is not particularly limited, and the sacrificial layer 710 may be removed through know methods.

Referring to (G) of FIG. 7, the active layer 700 including the first pre-doped part 730 and the second pre-doped part 750 may form a channel part 782. A method of forming of the active layer 700 is not particularly limited, and known methods may be used. For example, the method of forming of the active layer 700 may include forming an insulating layer on the active layer 700, forming a gate electrode on the insulating pattern, and doping a third dopant ion on the active layer 700 through a third ion implantation process.

During the patterning of the active layer 700, the active layer 700 located under the gate electrode may become the channel part 782. The gate electrode may serve as a self-aligned mask when implanting the third dopant ion, and may prevent the third dopant ion from being doped into the channel part 782. Accordingly, the first pre-doped part 730 and the second pre-doped part 750 existing in the active layer 700 may become a first doped part 784 and the second doped part 785 in the channel part 782. The first doped part 784 and the second doped part 785 may form the buried channel 330. Accordingly, the afterimage time TA may be reduced.

During the third ion implantation process, the active layer 700 not covered by the gate electrode may be a source part 781 and the drain part 783. In this case, the first pre-doped part 730 and the second pre-doped part 750 may exist in some of an upper area of the source part 781 and an upper area of the drain part 783. Generally, an amount of the third dopant ion implanted through the third ion implantation process may be greater than an amount of the first dopant ion 730 and an amount of the second dopant ion 750. Accordingly, the first pre-doped part 730 and the second pre-doped part 750 disposed in some of the upper area of the source part 781 and the upper area of the drain part 783 may be ignored.

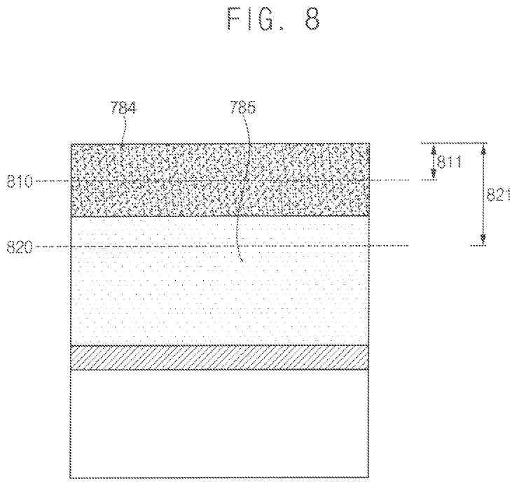

FIG. 8 is a cross-sectional view enlarging an area A of FIG. 7.

Referring to FIG. 8, the first doped part 784 may include a first average penetration depth 810 having the highest concentration of the first dopant ion 720 implanted through the first ion implantation process. The second doped part 785 may include a second average penetration depth 820 having the highest concentration of the second dopant ion 740 implanted through the second ion implantation process. During the first ion implantation process and the second ion implantation process, the first dopant ion 720 and the second dopant ion 740 may be accelerated by an acceleration voltage. An upper surface of the sacrificial layer 710 may be irradiated with the first dopant ion 720 and the second dopant ion 740. The first dopant ion 720 and the second dopant ion 740 may collide with an atomic structure constituting the sacrificial layer 700 or may be implanted into the sacrificial layer 700 without colliding with an atomic structure constituting the sacrificial layer 700. Accordingly, the first dopant ion 720 and the second dopant ion 740 doped in the sacrificial layer 700, first doped part 784, and the second doped part 785 may have a vertical concentration gradient. The vertical concentration gradient may have a Gaussian distribution. Accordingly, the first doped part 784 may include a first average penetration depth 810 having the highest concentration of the first dopant ion 720 and the second doped part 785 may include a second average penetration depth 820 having the highest concentration of the second dopant ion 740.

In this case, a first depth 811 of the first average penetration depth 810 in the first doped part 784 and a second depth 821 of the second average penetration depth 820 in the second doped part 785 may be adjusted by adjusting a magnitude of the acceleration voltage. In an embodiment, a first depth 811 from an upper surface of the first doped part 784 to the first average penetration depth 810 may be less than a second depth 821 from an upper surface of the first doped part 784 to the second average penetration depth 820. In this case, the first depth 811 may be about 20 nm or less. In another embodiment, the second depth 821 may be less than the first depth 811. In this case, the second depth 821 may be about 20 nm or less.

In addition, the concentration of the first dopant ion 720 and the concentration of the second dopant ion 740 may be adjusted by adjusting an operation time of the first ion implantation process and an operation time of the second ion implantation process. For example, a doping amount of the first dopant ion 720 in the first average penetration depth 810 may be about 10¹² ions/cm² or more. For example, the doping amount of the second dopant ion 740 in the second average penetration depth 820 may be about 10¹² ions/cm² or more.

The present inventive concept may be applied to various electronic device including transistors. For example, the present inventive concept may be applicable to numerous electronic devices such as display devices for vehicles, ships and aircraft, portable communication devices, display devices for exhibition or information transmission, medical display devices, etc.

It should be understood that embodiments described herein should be considered in a descriptive sense only not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing transistor, the method comprising:
forming an active layer on a base substrate;
forming a sacrificial layer on the active layer;
doping a first dopant ion in the active layer through a first ion implantation process;
removing the sacrificial layer;
forming a gate insulating layer; and
forming a gate electrode on the gate insulating layer.

2. The method of claim 1, wherein the sacrificial layer comprises a silicon oxide.

3. The method of claim 1, wherein the sacrificial layer is formed through a chemical vapor deposition method.

4. The method of claim 1, wherein the sacrificial layer is removed through a wet etching method.

5. The method of claim 1, wherein the sacrificial layer is removed through a chemical mechanical polishing (CMP) method.

6. The method of claim 1, wherein the first dopant ion comprises a group III element.

7. The method of claim 6, wherein the group III element comprises boron (B).

8. The method of claim 1, wherein the first dopant ion comprises a group V element.

9. The method of claim 8, wherein the group V element comprises phosphorus (P).

10. The method of claim 1, wherein a doping amount of the first dopant ion in the active layer has a peak in a region less than or equal to 20 nm from a surface of the active layer.

11. The method of claim 10, wherein the doping amount of the first dopant ion in the active layer is about 10¹² ions/cm² or more.

12. The method of claim 1, further comprising:
sequentially forming an insulating layer and a gate electrode forming layer on the active layer after removing the sacrificial layer;
patterning the gate electrode forming layer to form a gate electrode on the insulating layer;
forming an interlayer insulating layer on the gate electrode; and
forming a source electrode and a drain electrode on the interlayer insulating layer.

13. The method of claim 12, further comprising:
doping a second dopant ion on the active layer through a second ion implantation process after patterning the gate electrode using the patterned gate electrode as a mask.

14. The method of claim 12, wherein an upper surface of the doped part contacts with the insulating layer.

15. A method of manufacturing transistor, the method comprising:
forming an active layer on a base substrate;
forming a sacrificial layer on the active layer;
doping a first dopant ion in the active layer through a first ion implantation process;
doping a second dopant ion in the active layer through a second ion implantation process;
removing the sacrificial layer;
forming a gate insulating layer; and
forming a gate electrode on the gate insulating layer.

16. The method of claim 15, wherein the first dopant ion comprises a group III element and the second dopant ion comprises a group V element.

17. The method of claim 16, wherein the group III element comprises boron and the group V element comprises phosphorous.

18. The method of claim 15, wherein a doping amount of the first dopant ion in the active layer has a peak in a region less than or equal to 20 nm from a surface of the active layer
and a doping amount of the first dopant ion in the active layer is about 10¹² ions/cm² or more.

19. The method of claim 15, wherein a doping amount of the second dopant ion in the active layer has a peak in a region less than or equal to 20 nm from a surface of the active layer and a doping amount of the second dopant ion in the active layer is about 10¹² ions/cm² or more.
